(19) United States
(12) Patent Application Publication
(10) Pub. No.: US 2011/0248137 A1
(43) Pub. Date: Oct. 13, 2011

(54) Methods and Apparatus for Mounting Solar Panels

(76) Inventor: Nathan Barba, Goodyear, AZ (US)

(21) Appl. No.: 13/044,387

(22) Filed: Mar. 9, 2011

Related U.S. Application Data
(60) Provisional application No. 61/312,144, filed on Mar. 9, 2010.

(51) Int. Cl. H01L 23/12; H01L 31/18

(52) U.S. Cl. 248/309.1; 29/428

(57) ABSTRACT

A method and apparatus for mounting a solar panel to a surface according to various aspects of the present invention is configured to provide attachment of a solar panel to any suitable surface. The mounting system comprises a membrane and a frame coupled with the membrane. The frame is configured to receive the solar panel.

### CROSS-REFERENCE TO RELATED APPLICATIONS

The present application claims the benefit of and priority to Provisional Patent Application No. 61/312,144 entitled METHODS AND APPARATUS FOR MOUNTING SOLAR PANELS, filed on Mar. 9, 2010 and incorporates the disclosure of the application by reference.

### BACKGROUND OF INVENTION

Solar panels are used today in many areas and in many ways to generate electricity. Solar panels use light energy (photons) from the sun to generate electricity through the photovoltaic effect. The modules typically use wafer-based crystalline silicon cells or a thin-film cell utilizing cadmium telluride or silicon. Crystalline silicon, which is commonly used in the wafer form in photovoltaic (PV) modules, is derived from silicon, a commonly used semi-conductor.

Solar panels are known in the industry as photovoltaic modules or photovoltaic panels. The photovoltaic module or photovoltaic panel is a packaged interconnected assembly of photovoltaic cells, also known as solar cells. The photovoltaic module or solar panel is then used as a component in a larger photovoltaic system to offer electricity for commercial and residential applications. Because a single photovoltaic module or solar panel can only produce a limited amount of power or electrical output, many installations contain several modules or panels, commonly known as a photovoltaic array. A photovoltaic installation typically includes an array of photovoltaic modules or panels.

The current method to mount solar panel conventionally is to fasten the solar panel to some type of metallic rail or pipe, which is fastened a roof mount that is fastened to a roofing structure. Another method utilizes flexible adhered thin film photovoltaics integrated with thermopolyolefin “TPO” or reinforced polypropylene. The adhered thin film photovoltaic panels are not very efficient, and thus do not allow for maximum power output on liner surfaces. Additionally, since thin film photovoltaic panels are adhered, a repair to the module includes cutting out the panel and the membrane to which it is adhered.

### BRIEF DESCRIPTION OF THE DRAWINGS

A more complete understanding of the present invention may be derived by referring to the detailed description and claims when considered in connection with the following illustrative figures. In the following figures, like reference numbers refer to similar elements and steps throughout the figures.

FIG. 1 illustrates a perspective view of a solar panel mounting system in accordance with the present invention;

FIG. 2 illustrates a perspective view of a solar panel mounting system in accordance with the present invention with a solar panel attached thereto;

FIG. 3 illustrates a perspective view of a side rail of the solar panel mounting system accordance with the present invention;

FIG. 4 illustrates a front view of a side rail of the solar panel mounting system accordance with the present invention;

FIG. 5 illustrates a partial perspective view of a side rail of the solar panel mounting system accordance with the present invention;

FIG. 6 illustrates an end view of a side rail of the solar panel mounting system accordance with the present invention; and

FIG. 7 illustrates a perspective, end view of an attachment portion of the solar panel mounting system accordance with the present invention.

Elements and steps in the figures are illustrated for simplicity and clarity and have not necessarily been rendered according to any particular sequence. For example, steps that may be performed concurrently or in different order are illustrated in the figures to help to improve understanding of embodiments of the present invention.

### DETAILED DESCRIPTION OF EXEMPLARY EMBODIMENTS

Methods and apparatus for mounting solar panels to a surface according to various aspects of the present invention may comprise a solar panel mounting system comprising a frame and a membrane. The particular implementations shown and described are illustrative of the invention and its best mode and are not intended to otherwise limit the scope of the present invention in any way. Indeed, for the sake of brevity, conventional manufacturing, connection, preparation, and other functional aspects of the system may not be described in detail. Furthermore, the connecting lines shown in the various figures are intended to represent exemplary functional relationships and/or steps between the various elements. Many alternative or additional functional relationships or physical connections may be present in a practical system.

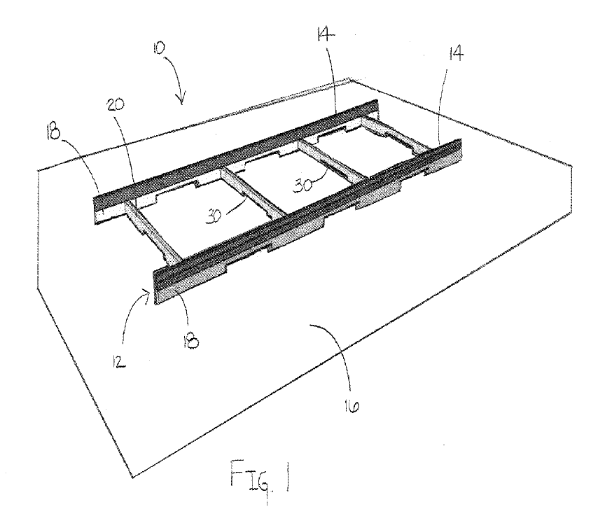

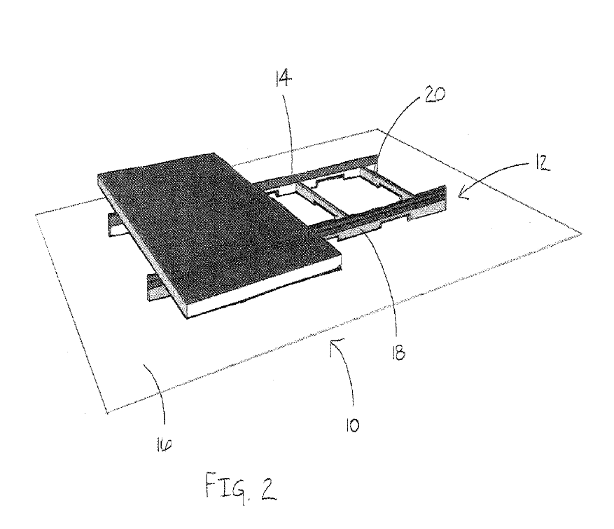

Referring now to FIGS. 1 and 2, a solar panel mounting system 10 according to various aspects of the present invention will be discussed. The mounting system 10 according to various aspects of the present invention provides for the installation of solar panels to a geomembrane liner, roof liner material or other suitable surfaces. In an exemplary embodiment, the mounting system 10 provides for direct attachment to a geomembrane liner that covers surfaces, such as landfills, floating covers, surfaces floating on a liquid, ash pile covers, mine tailing liners, mountainside covers, hill side covers, roof liners or any liner. The mounting system 10 has multiple benefits such as erosion control, non-corrosive properties, low-profile, universal topographic integration, easy deployment around the globe, electricity generation integrated with rain water collection, and use of land once considered unusable (i.e., landfills, mine tailings, floating covers). The solar panel shown in FIG. 2 can be any known or contemplated solar panel.

In some embodiments, the mounting system may comprise a frame 12 and an attachment portion 14. It should be understood that the frame 12 and the attachment portion 14 may be a single piece or multiple pieces. In some embodiments, the mounting system 10 may comprise a membrane 16. The membrane 16 may comprise a thermoplastic membrane. In some embodiments the frame 12 may be attached to the membrane 16 by any suitable method. In some embodiments, the frame 12 may be attached to the membrane 16 by a non penetrating attachment element, such as, fusion, radio frequency (RF), high frequency, dielectric, extrusion welding and the like. The membrane 16 may then be attached to any suitable attachment surface at the job site, such as another sheet of a solar integrated membrane to create a large scale solar field. Other contemplated attachment surfaces may comprise coverings for landfills, mine tailings, floating covers, ash piles, manure piles. It should be understood that the covering may comprise geomembrane liners and the like. The membrane 16 may be attached to the covering by fusion, radio frequency (RF), high frequency, dielectric, extrusion welding, etc. Other attachment surfaces may comprise roof tops, temporary shelters, refrigerated semi-truck trailers, smoke stacks, water towers, or any other lined container, structure or surface, as will be discussed in detail below.

Additionally, the mounting system 10 does not utilize penetrations directly into the geomembrane liners. The non penetrating attachment element utilizing fusion, radio frequency (RF), high frequency, dielectric, extrusion welding and the like provides a mounting system that is leak proof and provides a tight liquid seal against environmental elements and on the materials in landfills, mine tailings, floating covers, ash piles, manure piles etc. Some advantages of not using a penetrating method is that the connection between the frame 12, the membrane 16, and geomembrane liners include liners that are leak proof, provide a liquid tight seal, a strong bond from welding and the ability of manufacturer to continue warranty of liner integrity.

The membrane 16 may comprise any suitable material that allows for the attachment to materials, conditions, environment, surface, etc. which may be located at a job site or any other destination where the solar panels are to be installed. The material for the membrane 16 may be selected according to any appropriate properties, such as ultraviolet resistant and/or chemical resistant. The membrane 16 may comprise any material that allows for coupling with any suitable attachment surface at a job site, such as thermoplastic olefin (TPO), high density polypropylene (HDPE), reinforced polypropylene (RPP), polyvinylchloride (PVC), ethylene propylenediene Monomer (EPDM), nylons, etc, or any type of geothermal liner, geosynthetic membrane or roofing membrane. The membrane 16 may comprise any suitable shape to facilitate attachment to the covering, geomembrane liner or suitable attachment surface.

In one embodiment, the frame 12 may be coupled directly to the covering, geomembrane liner, surface or surface material at a job site or any other location. In this embodiment, the non penetrating attachment element utilizing fusion, radio frequency (RF), high frequency, dielectric, extrusion welding and the like may be used.

In some embodiments, the frame 12 may comprise a pair of side frames 18. In one embodiment, the frame may comprise at least one center frame 20. Additionally, while there are four center frames shown in FIGS. 1 and 2, it should be understood that this number is not meant to be limiting and any suitable number of center frames may be used.

In some embodiments, the frame 12 may be comprised of a solid material or may have portions removed (cutouts) to allow for air cooling and improved water flow (i.e., no water retention). The frame 12 may comprise an aperture for facilitating attachment of the center frame. In some embodiments, the frame 12 may comprise a white HDPE “marine board” or UV inhibited copolymer Polypropylene. The HDPE “marine board” or UV inhibited copolymer Polypropylene are both white and have UV inhibitors for long life in sun. The HDPE “marine board” otherwise known as “Densetec HDPE” or the UV inhibited copolymer Polypropylene (CoPoly PolyPro) also reflects heat. It should be understood that various frames 12 and membrane 16 combinations may be used. For example, in one embodiment, if a HDPE frame is utilized, the frame may be welded to a HDPE/LDPE/LLDPE membrane. In another embodiment, if a CoPoly PolyPro frame is utilized, the frame may be welded to TPO/RPP/PVC membrane. The marine board material may be comprised of polyethylene and polyethylene hexane copolymer plus additives. The marine board material may comprise beneficial properties, such as, be fully recyclable, reflect light, have an UV inhibitor, withstand temperatures as high as 180 Degrees F. and cold as −120 Degrees F., have a tensile strength of 4000 psi at yield, and have an ultimate elongation of >600%. Additionally, the frame 12 may be comprised of any suitable material, such as a plastic and/or polymer. The material may be selected according to any appropriate properties, such as chemical and/or ultraviolet (UV) resistance.

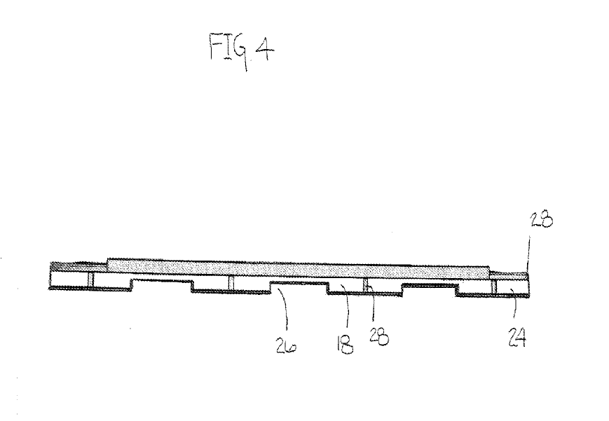

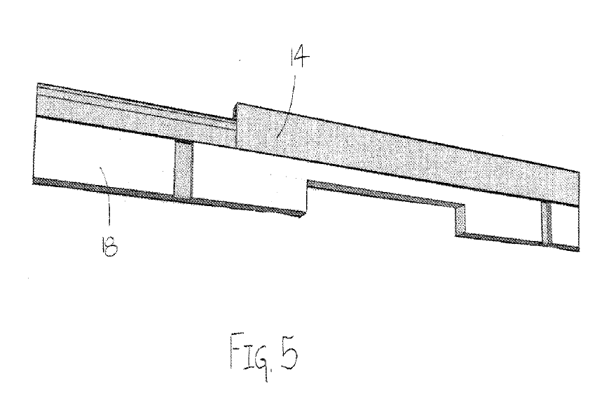

Referring now to FIGS. 1-6 the side frames 18 will be discussed. In some embodiments, the side frames 18 may comprise an upper portion 22 and a lower portion 24. The side frames 18 may comprise a cutout portion 26 to allow for air cooling and improved water flow. The side frame 18 may comprise an aperture 28 used to facilitate attachment of the center frame 20. The center frame 20 may comprise a pair of ends that are received in the apertures 28 on the side frame 18. The center frame 20 may be coupled to the side frame 18 by any suitable attachment method to include but not limited to fusion, RF, high frequency, dielectric, extrusion welding, etc. The center frame 20 may include a cutout portion(s) 30 to allow for air cooling and improved water flow.

In some embodiments, the lower portions of the side frame 18 and center frame 20 may be attached to an upper surface of the membrane 16 by fusion, RF, high frequency, dielectric, extrusion welding, etc. Any suitable attachment method may be used to attach the frame 14 to the membrane 16.

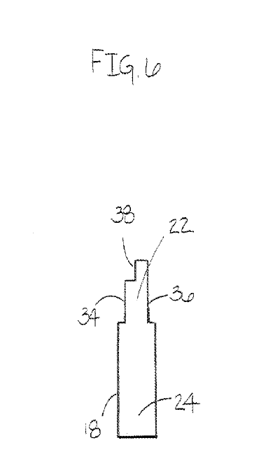

The side frames 18 may be oriented to facilitate a coupling of a solar panel (see FIG. 2) thereto. As shown in FIG. 6, the upper portion 22 of the side frame 18 may be shaped as shown and includes a coupling member 32. The coupling member 32 may comprise a pair of side cutouts 34, 36 and a top cutout 38 that facilitate attachment to the attachment member 14. In an additional embodiment, not shown, the coupling member 32 may comprise a pair of side cutouts. It should be understood that the coupling member 32 may be any suitable shape to allow for attachment to the attachment member 14.

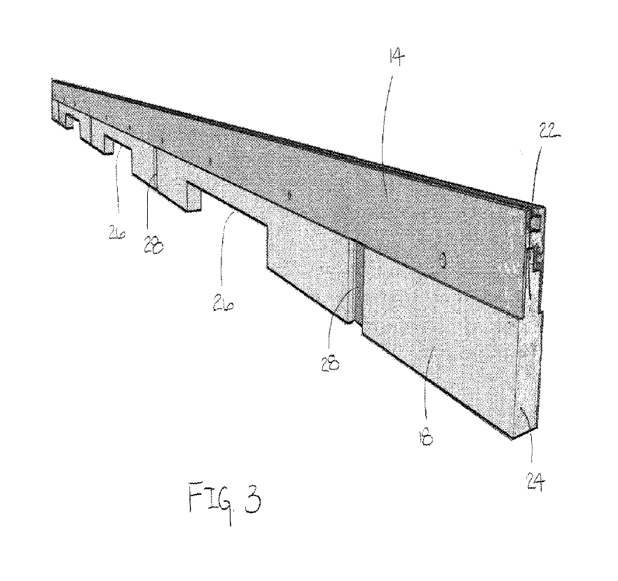

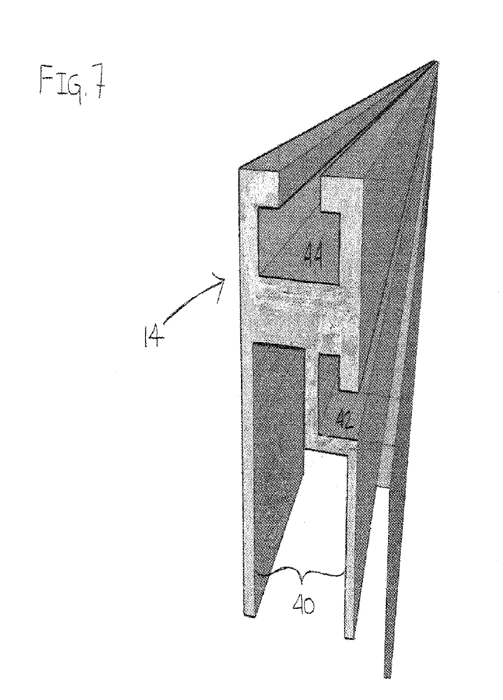

Referring now to FIGS. 3 and 7, the attachment member 14 according to various aspects of the present invention may be shaped as shown and coupled to the coupling member 32 on the upper portion 22 of the side frame 18. In one exemplary embodiment, the attachment member 14 may be coupled to the side frame 18 via stainless steel bolts, washers and nuts (not shown). However it should be understood that any suitable attachment method may be used.

Referring now to FIG. 7, in some embodiments, the attachment member 14 may comprise a channel that facilitates attachment of the solar panels to the frame 12. It should be understood that any suitable material may be used for the attachment portion. The attachment member 14 may comprise a lower channel 40, a side channel 42, and an upper channel 44. The lower channel 40 may be shaped as shown and oriented to receive the coupling member 32 of the side frames 18. As stated above, the attachment member 14 may be coupled to the coupling member 32 on the upper portion 22 of the side frame 18 via bolts or any suitable attachment method.

The side and upper channels 42, 44 may couple the solar panels to the frame 12. The orientation of the side and upper channels 42, 44 may allow for a number of attachment methods. However, the orientation of the channels is not meant to be limiting and other channel configurations are contemplated. One example of an attachment method is the use of the “top down” clips which would utilize the upper channel 44 for attachment of the solar panels to the frame.

However, the solar panels may be attached to the frame in a number of additional ways. In an embodiment, a pipe may be connected to the frame 12 utilizing u-bolts and clamps. A solar panel may then be attached to frame 12 via the pipe. In an additional embodiment, tilt legs may be connected to the frame 12 to allow for fixed tilting. In an additional embodiment, a metal C-Channel (or upside down U) rail may be attached to a frameless solar panel via adhesive and then coupled with the upper portion 22 of the side frames 18.

The mounting system 10 according to various aspects of the present invention provides for the installation of solar panels to a geomembrane liner or roof liner material. In an exemplary embodiment, the mounting system 10 provides for the direct attachment to a geomembrane liner cover for landfills, floating covers, ash pile covers, mine tailing liners, and roof liners or any liner, mountainside or hill side. The combination of metal attachment members, rigid plastic or polymer frames integrated with flexible geomembrane liners (TPO, HDPE, RPP, etc) and solar panels have multiple benefits such as erosion control, non-corrosive properties, low-profile, universal topographic integration, easy deployment around the globe, electricity generation integrated with rain water collection, and use of land once considered unusable (i.e., landfills, mine tailings, floating covers).

The mounting system 10 further allows for the universal attachment of existing flat plate solar PV modules or PV glass laminates. The mounting system 10 can be made to fit any size or dimension and can be attached to various types of membranes/liners. Additionally, the mounting system 10 does not utilize penetrations directly into the geomembrane liners. Some advantages to not using penetrations directly into the geomembrane liners include liners that are leak proof, provide a liquid tight seal, strong bond from welding and ability of manufacturer to continue warranty of liner integrity.

In some embodiments the membrane may be installed on flat surface or any type of topography. Depending on the slope, weight and or size of array, the mounting system 10 may also be reinforced with straps or cables to give additional support.

The mounting system 10 additionally allows for the installation and deployment of solar energy equipment on spaces previously considered useless, such as landfills, mine tailings, floating covers, ash piles, and manure piles. The mounting system 10 may also be put on roof tops or any other lineable surface. The mounting system 10 may also be attached with membranes that are used for temporary shelter, refrigerated semi-truck trailers, smoke stacks, water towers, or any other lined container or structure. There currently isn't a way to attach flat plate solar modules to tilted surfaces without penetrating surface. The current method utilizes flexible adhered thin film photovoltaics. These panels are not as efficient and thus do not allow for maximum power output on liner surfaces.

The mounting system 10 also may allow for air to pass beneath the module and is lifted above the service in case of water retention. The mounting system 10 also allows for interchangeability of modules for maintenance. In contrast, with a flexible adhered thin film cannot maintained or replaced without tearing and removing.

There are a number of advantages gained with by utilizing the mounting system 10 described herein. The benefits of the system is due to the membrane this allows for: erosion control, dust mitigation, evaporation control (floating system), rain water harvest/shedding, vegetation control, low profile, possible additional power generation because of reflectivity, keeps water from entering contaminated area (mine tailing, landfill), allows for collection of Biogases such as methane, corrosion Resistant

Additionally there are a number of benefits of the mounting system 10 described herein versus what's currently available. The mounting system 10 may allow for multiple solar panels, use of conventional mounting hardware, the mounting system can be grounded, tilt legs can be attached for tilt, panels can be removed for service, and metal rails provide a rigid system as plastic may change shape in different weather.

There are a number of applications associated with the mounting system 10 described including but not limited applications of systems 10 to slopes, bodies of water, mine tailings, landfill covers, water tanks, commercial rooftops, residential rooftops, ash piles, corn piles, methane farms, and on top of temporary tents or housing for emergency. Additionally, the mounting system 10 described herein may also be used in any land that a trench can be dug for anchoring. Some examples include energy production, rain water collection, erosion control, non-corrosive material, electricity generation integrated with rain water collection, vegetation control, use of land once considered unusable (i.e. landfills, mine tailings, bodies of water), universal topographic installation, low profile unlike large tracking arrays. Additionally, the mounting system 10 is durable, long lasting, low maintenance, light weight, featuring enhanced cooling properties depending on materials as well as reflective properties of membrane which are easily deployable throughout the globe for land and/or water applications.

In the foregoing description, the invention has been described with reference to specific exemplary embodiments. Various modifications and changes may be made, however, without departing from the scope of the present invention as set forth. The description and figures are to be regarded in an illustrative manner, rather than a restrictive one and all such modifications are intended to be included within the scope of the present invention. Accordingly, the scope of the invention should be determined by the generic embodiments described and their legal equivalents rather than by merely the specific examples described above. For example, the steps recited in any method or process embodiment may be executed in any appropriate order and are not limited to the explicit order presented in the specific examples. Additionally, the components and/or elements recited in any system embodiment may be combined in a variety of permutations to produce substantially the same result as the present invention and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

The present invention has been described above with reference to an exemplary embodiment. However, changes and modifications may be made to the exemplary embodiment without departing from the scope of the present invention. These and other changes or modifications are intended to be included within the scope of the present invention.

1. A mounting system for mounting a solar panel to a surface, the mounting system comprising:
a membrane configured to be coupled to the surface;
a frame coupled with the membrane; wherein the frame is configured to receive the solar panel.

2. A mounting system according to claim 1, wherein the membrane comprises a flexible material.

3. A mounting system according to claim 1, wherein the frame is coupled with the membrane by a non penetrating attachment element.

4. A mounting system according to claim 1, wherein the non penetrating attachment element comprises welding.

5. A mounting system according to claim 5, wherein the welding may comprise one of fusion, radio frequency, high frequency, dielectric, and extrusion welding.

6. A mounting system according to claim 1, wherein the frame comprises a pair of spaced apart side frames.

7. A mounting system according to claim 7, wherein the frame comprises an attachment portion coupled with the frame, wherein the attachment portion couples the solar panel to the frame.

8. A mounting system according to claim 1, wherein the membrane comprises a thermo plastic membrane.

9. A mounting system according to claim 8, wherein the thermo plastic material may comprise one of thermoplastic olefin (TPO), high density polypropylene (HDPE), reinforced polypropylene (RPP), polyvinylchloride (PVC), and ethylene propylene diene Monomer (EPDM).

10. A mounting system according to claim 1, wherein the membrane is coupled with the surface by a non penetrating attachment element.

11. A method of mounting a solar panel to a membrane, the method comprising:
attaching a mounting frame to a surface of the membrane;
preventing penetration of the mounting frame through the membrane; and
coupling a solar panel to the mounting frame.

12. The method according to claim 11, further comprising creating a liquid tight seal between the mounting frame and the surface of the membrane.

13. The method according to claim 11, further comprising providing at least one opening between the mounting frame and the membrane.

14. The method according to claim 13, further comprising channeling water on the surface of the membrane through the at least one opening.

15. The method according to claim 11, further comprising fusing a portion of the mounting frame to the surface of the membrane.

16. The method according to claim 11, further comprising welding a portion of the mounting frame to the surface of the membrane.

17. The method according to claim 11, further comprising preventing liquids below the surface of the membrane from penetrating the membrane.

18. The method according to claim 11, further comprising preventing erosion of material below the surface of the membrane.

19. The method according to claim 11, further comprising positioning the membrane over one of a landfill, a flue ash pile, and mining tailings.

20. The method according to claim 11, further comprising coupling the membrane to one of a temporary shelter, a refrigerated semi-truck trailer, a smoke stack, and a water tower.
